(19) United States
(12) Patent Application Publication
(10) Pub. No.: US 2020/0350339 A1
(43) Pub. Date: Nov. 5, 2020

(54) ARRAY SUBSTRATE AND MANUFACTURING METHOD THEREOF, DISPLAY PANEL AND DISPLAY DEVICE

(71) Applicants: BEIJING BOE OPTOELECTRONICS TECHNOLOGY CO., LTD., Beijing (CN); BOE TECHNOLOGY GROUP CO., LTD., Beijing (CN)

(72) Inventors: Huiying LI, Beijing (CN); Bin LI, Beijing (CN); Weixiong CHEN, Beijing (CN); Hao CHENG, Beijing (CN)

(21) Appl. No.: 16/643,087

(22) PCT Filed: Mar. 28, 2019
(86) PCT No.: PCT/CN2019/079969

§ 371 Date: Feb. 28, 2020

(30) Foreign Application Priority Data
Apr. 13, 2018 (CN) 201810332447.7

(51) Int. Cl. H01L 27/12

(52) U.S. Cl. CPC H01L 27/124; H01L 27/1259

(57) ABSTRACT

This disclosure relates to an array substrate and a manufacturing method thereof, as well as a corresponding display panel and display device. The array substrate includes a base substrate, a first electrode layer, an insulating layer and an electrically conductive member on the base substrate sequentially, at least one first via hole passing through the insulating layer, and at least one first electrical conductor. Each first electrical conductor is filled in a corresponding first via hole to electrically connect the first electrode layer and the electrically conductive member.

### RELATED APPLICATIONS

The present application claims the priority of the Chinese patent application No. 201810332447.7 filed on Apr. 13, 2018, the entire disclosure of which is incorporated herein by reference.

### TECHNICAL FIELD

This disclosure relates to the field of display technologies, and in particular to an array substrate and a manufacturing method thereof, as well as a corresponding display panel and display device.

### BACKGROUND

Thin film transistor is usually referred to as TFT. Each pixel on a liquid crystal display is driven by a thin film transistor integrated behind it, so as to display screen information with high speed, high brightness and high contrast. Thin film transistor liquid crystal display (TFT-LCD) is one of many liquid crystal displays.

In a liquid crystal display panel, a flexible printed circuit (FPC) needs to be bonded. By taking advantage of the integrated wiring configuration and thin thickness of the flexible printed circuit, digital signals are converted into images and presented through the liquid crystal screen. Usually, the flexible printed circuit is electrically connected via an indium tin oxide (ITO) layer with a metal conductive layer arranged under the ITO layer, so as to transmit signals.

In a conventional scheme, the ITO layer is generally arranged on an insulating protective layer. Therefore, when the protective layer is displaced or peeled off, the lateral extension of the protective layer will lead to displacement or peeling of the ITO layer at the same time. In this case, the peeling of the ITO layer will cut off the connection between the flexible printed circuit and the metal conductive layer under the flexible printed circuit such that signals cannot be transmitted normally and thus the display performance of the liquid crystal display panel will be affected seriously.

### SUMMARY

According to an aspect of this disclosure, an array substrate is provided. Specifically, the array substrate includes: a base substrate; a first electrode layer, an insulating layer and an electrically conductive member on the base substrate sequentially; at least one first via hole passing through the insulating layer; and at least one first electrical conductor, wherein each first electrical conductor is filled in a corresponding first via hole to electrically connect the first electrode layer and the electrically conductive member.

According to a specific implementation, in the array substrate provided in the embodiments of this disclosure, the electrically conductive member includes a transparent conductive layer or a flexible printed circuit.

According to a specific implementation, in the array substrate provided in the embodiments of this disclosure, the first electrical conductor includes a negative photoresist doped with electrically conductive particles.

According to a specific implementation, in the array substrate provided in the embodiments of this disclosure, the first electrode layer includes a plurality of first electrodes arranged in an array, each first electrode being electrically connected with the electrically conductive member via one or more of the first electrical conductors.

According to a specific implementation, in the array substrate provided in the embodiments of this disclosure, the insulating layer includes a first insulating layer facing the first electrode layer and a second insulating layer on the first insulating layer.

According to a specific implementation, the array substrate provided in the embodiments of this disclosure further includes: a second electrode layer between the first insulating layer and the second insulating layer; at least one second via hole passing through the second insulating layer; and at least one second electrical conductor, wherein each second electrical conductor is filled in a corresponding second via hole to electrically connect the second electrode layer and the electrically conductive member.

According to a specific implementation, in the array substrate provided in the embodiments of this disclosure, the second electrode layer includes a plurality of second electrodes arranged in an array, each second electrode being electrically connected with the electrically conductive member via one or more of the second electrical conductors.

According to a specific implementation, in the array substrate provided in the embodiments of this disclosure, the first electrical conductor has a thickness greater than that of the insulating layer. According to another aspect of this disclosure, a display panel is further provided, including the array substrate described in any of the above embodiments.

According to yet another aspect of this disclosure, a display device is further provided, including the display panel described in any of the above embodiments.

According to still another aspect of this disclosure, a manufacturing method for an array substrate is further provided. The manufacturing method includes: forming a first electrode layer and an insulating layer sequentially on a base substrate; forming at least one first via hole passing through the insulating layer; filling a corresponding first electrical conductor in each first via hole; and forming an electrically conductive member at least partially covering the insulating layer such that the electrically conductive member is electrically connected with the first electrode layer via the first electrical conductors.

According to a specific implementation, in the manufacturing method for an array substrate provided in the embodiments of this disclosure, the step of filling a corresponding first electrical conductor in each first via hole includes: applying a negative photoresist doped with electrically conductive particles on the insulating layer on which the first via holes have been formed, and exposing and developing the negative photoresist by using a mask to form at least one first electrical conductor filled in a corresponding first via hole respectively.

According to a specific implementation, in the manufacturing method for an array substrate provided in the embodiments of this disclosure, the insulating layer includes a first insulating layer facing the first electrode layer and a second insulating layer on the first insulating layer; the step of forming at least one first via hole passing through the insulating layer includes: forming at least one first via hole passing through the first insulating layer and the second insulating layer; and the manufacturing method further includes: forming a second electrically conductive layer between the first insulating layer and the second insulating layer; forming at least one second via hole passing through the second insulating layer, and filling a corresponding second electrical conductor in each second via hole to electrically connect the electrically conductive member and the second electrode layer.

According to a specific implementation, in the manufacturing method for an array substrate provided in the embodiments of this disclosure, the step of filling a corresponding first electrical conductor in each first via hole and the step of filling a corresponding second electrical conductor in each second via hole are executed at the same time by: applying an electrically conductive material on the insulating layer on which the first via holes and the second via holes have been formed; and removing by a patterning process all other electrically conductive material that is applied except for the part at positions of the first via holes and the second via holes, to form the first electrical conductors and the second electrical conductors filled in the first via holes and the second via holes respectively.

### BRIEF DESCRIPTION OF THE DRAWINGS

The above and/or additional aspects and advantages of this disclosure will become clear through description of the embodiments with reference to the drawings, wherein:

FIG. 1 is a schematic structure view of an array substrate according to the related art;

FIG. 2 is an enlarged view of part of a transparent conductive material in the array substrate according to the related art;

FIG. 3 is a schematic structure view of an array substrate according to an embodiment of this disclosure;

FIG. 4 is a schematic structure view of an array substrate according to another embodiment of this disclosure;

FIG. 5 is a schematic structure view of an array substrate according to yet another embodiment of this disclosure;

FIG. 6 is a flow chart of a manufacturing method for an array substrate according to an embodiment of this disclosure;

FIG. 7 is a flow chart of a manufacturing method for an array substrate according to another embodiment of this disclosure;

FIG. 8 is a schematic structure view of the array substrate when the via holes are etched in the first insulating layer and the second insulating layer in the manufacturing method for an array substrate according to an embodiment of this disclosure; and

FIG. 9 is a schematic structure view of the array substrate when the applied electrically conductive material is exposed in the manufacturing method for an array substrate according to an embodiment of this disclosure.

### DETAILED DESCRIPTION OF EMBODIMENTS

The embodiments of this disclosure will be described below in detail. Examples of the embodiments are shown in the drawings, wherein same or similar signs are used to indicate same or similar elements or elements having same or similar functions throughout the description. The embodiments described below with reference to the drawings are exemplary, so they are only used for explaining this disclosure, rather than limiting this disclosure in any possible way.

Those skilled in the art can understand that the singular forms of “a”, “one”, “said” and “the” used herein can also include plural forms unless specified otherwise. It should be further understood that the wording “include” used in the description of this disclosure refers to the presence of stated feature, integer, step, operation, element and/or component, but does not exclude the presence or addition of one or more other features, integers, steps, operations, elements, components and/or a group thereof. It should be understood that when we describe an element as being “connected” or “coupled” to another element, it can be connected or coupled to the other element directly, or by an intermediate element. Besides, the wording “connect” or “couple” used herein can include wireless connection or wireless coupling. The wording “and/or” used herein includes all of one or more listed items associated therewith or any unit and all combination thereof.

Those skilled in the art should understand that, unless otherwise defined, all terms used herein (including both technical terms and scientific terms) have the same meanings as generally understood by one having ordinary skills in the art of this disclosure. It should be further understood that terms such as those defined in a general dictionary should be understood as having meanings consistent with the context of the prior art and should not be construed by using ideal or excessively formal meanings unless specifically defined as defined herein.

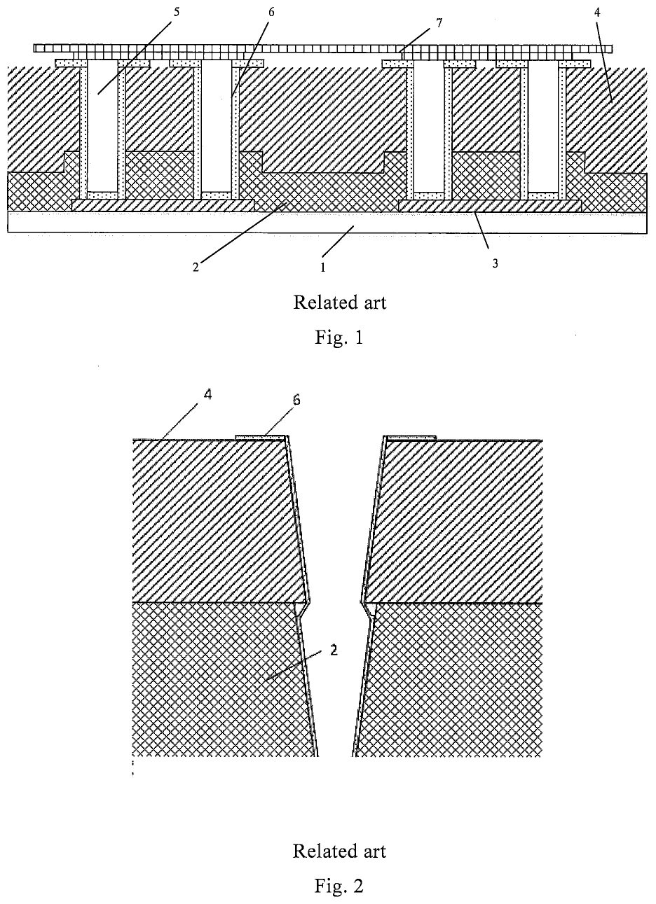

FIG. 1 is a schematic structure view of an array substrate according to the related art. As shown in FIG. 1, in the related art, the array substrate includes a base substrate 1, a first insulating layer 2, a first electrode layer 3, a second insulating layer 4, a via hole 5 and a transparent conductive material 6. Specifically, the first electrode layer 3 is located on the base substrate 1, and may include one or more separate first electrodes 30 for example. Besides, the first insulating layer 2 is arranged on the first electrode layer 3 and the second insulating layer 4 is arranged on the first insulating layer 2. As shown in FIG. 1, according to the related art, the array substrate includes a plurality of via holes 5, and each via hole 5 passes through the first insulating layer 2 and the second insulating layer 4, thereby exposing at least part of the first electrode layer 3 below. Continuously, as shown in FIG. 1, a flexible printed circuit 7 covers the second insulating layer 4, and is electrically connected with the first electrode layer 3 below by means of the transparent conductive material 6 applied at least on a bottom wall and a side wall of each via hole 5, thereby transmitting signals between the flexible printed circuit 7 and the first electrode layer 3 for example.

It is found by the applicant that the transparent conductive material 6 electrically connected with the flexible printed circuit 7 is formed in the via holes in the first insulating layer 2 and the second insulating layer 4. Therefore, when the first insulating layer 2 and/or the second insulating layer 4 are/is displaced or peeled off, the lateral extension of the insulating layer will lead to displacement or peeling of the transparent conductive material 6 at the same time. In this case, the peeling of the transparent conductive material 6 will cut off the electrical connection between the flexible printed circuit 7 and the first electrode layer 3 such that signals cannot be transmitted normally therebetween and thus the display performance of the liquid crystal display panel will be affected seriously.

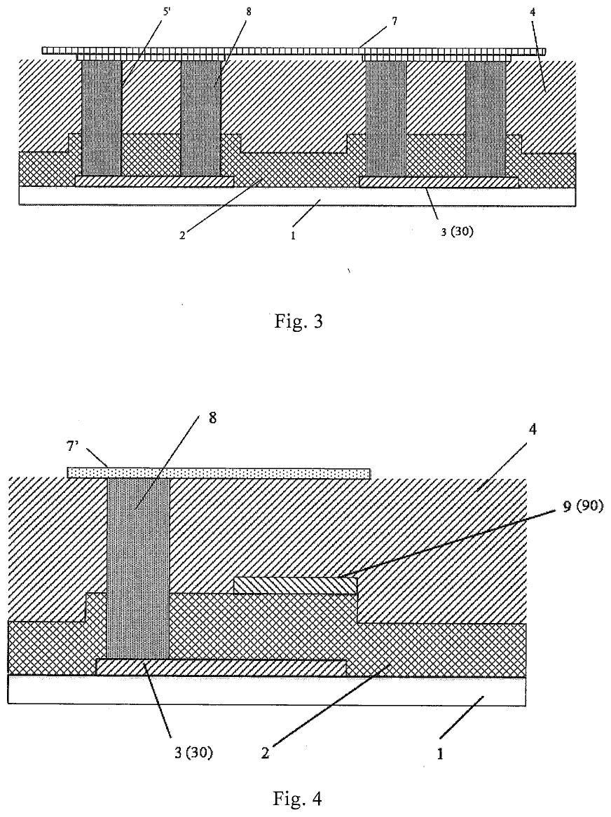

Besides, it is further found by the applicant that when the via holes 5 are fabricated in a poor process, hole walls of the via holes 5 may have large slopes, or diameters of the via holes in the first insulating layer 2 and the second insulating layer 4 may be different. In this case, as shown in FIG. 2, at an intersecting position of the first insulating layer 2 and the second insulating layer 4, or at the joining position of the side wall and the bottom wall of the via hole, the transparent conductive material 6 has a thin thickness, which is apt to cause abnormality in the connection performance of the transparent conductive material 6 and reduce both the entire performance of the liquid crystal display panel and the user experience.

The embodiments of this disclosure will be described in detail with reference to the drawings.

As shown in FIG. 3 and FIG. 4, FIG. 3 and FIG. 4 show schematic structure views of an array substrate according to an embodiment of this disclosure respectively, and according to the embodiments of this disclosure, an array substrate is provided. Referring to FIG. 3, the array substrate may include: a base substrate 1, and an insulating layer (including a first insulating layer 2 and a second insulating layer 4 superimposed on each other for example), a first electrode layer 3 and an electrically conductive member (a flexible printed circuit 7 for example) arranged on the base substrate 1 sequentially. Specifically, as shown in FIG. 3, the first electrode layer 3 may be a patterned first electrode layer 3 and include a plurality of first electrodes 30 arranged in an array, wherein only two first electrodes 30 are shown in the drawing for clarity. Besides, the array substrate further includes at least one first via hole 5′ passing through the insulating layer (e.g., the first insulating layer 2 and the second insulating layer 4), such as four first via holes 5′ as shown in FIG. 3, so as to expose at least part of the first electrode layer 3 (particularly, the first electrodes 30) below the insulating layer, and a corresponding first electrical conductor 8 is filled in each first via hole 5′. In this way, electrical connection between the electrically conductive member located above and the first electrode layer 3 located below can be achieved by means of the first via hole 5′ and the first electrical conductor 8 filled in the first via hole 5′.

Specifically, in the embodiments of this disclosure, the insulating layer may either be single layered, or multilayered. For example, as mentioned above, the insulating layer may include both a first insulating layer 2 and a second insulating layer 4. As an example, in an embodiment of this disclosure, the first electrode layer 3 may be a gate layer, which includes a plurality of gates arranged in an array, for instance. Apparently, it is obvious that the first electrode layer 3 may also be an electrode layer of other types.

According to a specific embodiment of this disclosure, in the above array substrate, the electrically conductive member includes a transparent conductive layer 7′ located above the insulating layer, as shown in FIG. 4. In this case, the first electrical conductor 8 is used for electrically connecting the transparent conductive layer 7′ and the first electrode layer 3. Alternatively, in other embodiments of this disclosure, the electrically conductive member may further include a flexible printed circuit 7 bound in the binding region of the array substrate for example, as shown in FIG. 3. In this case, the first electrical conductor 8 is used for electrically connecting the flexible printed circuit 7 and the first electrode layer 3.

According to an embodiment of this disclosure, in the array substrate, the first electrode layer 3 (particularly, each first electrode 30) is electrically connected with the electrically conductive member via the first electrical conductor 8 filled in the first via hole 5′. Therefore, when the electrically conductor member includes the flexible printed circuit 7 bound in the binding region of the array substrate, according to an embodiment of this disclosure, the flexible printed circuit 7 will be electrically connected to the first electrode layer 3 or the first electrodes 30 by means of the first electrical conductor 8. In this case, even if the insulating layer (e.g., the first insulating layer 2 and/or the second insulating layer 4) is displaced or peeled off, the first electrical conductor 8 filled in the first via hole 5′ will not be displaced or peeled off by the lateral extension of the insulating layer at all. In other words, the flexible printed circuit 7 still can be in electrical connection with the first electrode layer 3 in this case, thereby avoiding the problem that the signals cannot be transmitted normally due to the peeling of the insulation layer, and greatly reducing the adverse effects on the display performance of the liquid crystal display panel.

Besides, according to other embodiments of this disclosure, the electrically conductive member may further include a transparent conductive layer 7′ located on the insulating layer (particularly, the second insulating layer 4). In this case, in the array substrate, the transparent conductive layer 7′ is electrically connected with the first electrode layer 3 or the first electrodes 30 via the first electrical conductor 8. As can be seen, there is no need to fill the transparent conductive layer 7′ in the first via hole 5′. As a result, the transparent conductive layer 7′ has an even thickness, which is helpful for improving the entire performance of the liquid crystal display panel.

Optionally, in an embodiment of this disclosure, the base substrate 1 may be a glass substrate. However, it is obvious for those skilled in the art that the base substrate 1 may also be a substrate of other types.

Optionally, to reduce the costs of the material, in a specific embodiment of this disclosure, the material of the first electrical conductor 8 may be a photoresist doped with electrically conductive particles.

Further optionally; in a specific embodiment of this disclosure, the material of the first electrical conductor 8 includes a negative photoresist doped with electrically conductive particles. In this way, during the subsequent manufacture of the first electrical conductor 8, the same mask for fabricating the insulating layer (particularly, the second insulating layer 4) may be used, thereby saving both the production time and the production costs.

Optionally, in a specific embodiment of this disclosure, the first electrical conductor 8 has a thickness greater than that of the insulating layer. Specifically, the thickness of the first electrical conductor 8 is greater than the sum of the thickness of the first insulating layer 2 and the thickness of the second insulating layer 4, which can ensure that the first electrical conductor 8 is better filled in the first via hole 5′.

Optionally, in a specific embodiment of this disclosure, the transparent conductive layer 7′ may be an ITO layer, or an IZO layer, or a composite film layer of ITO and IZO.

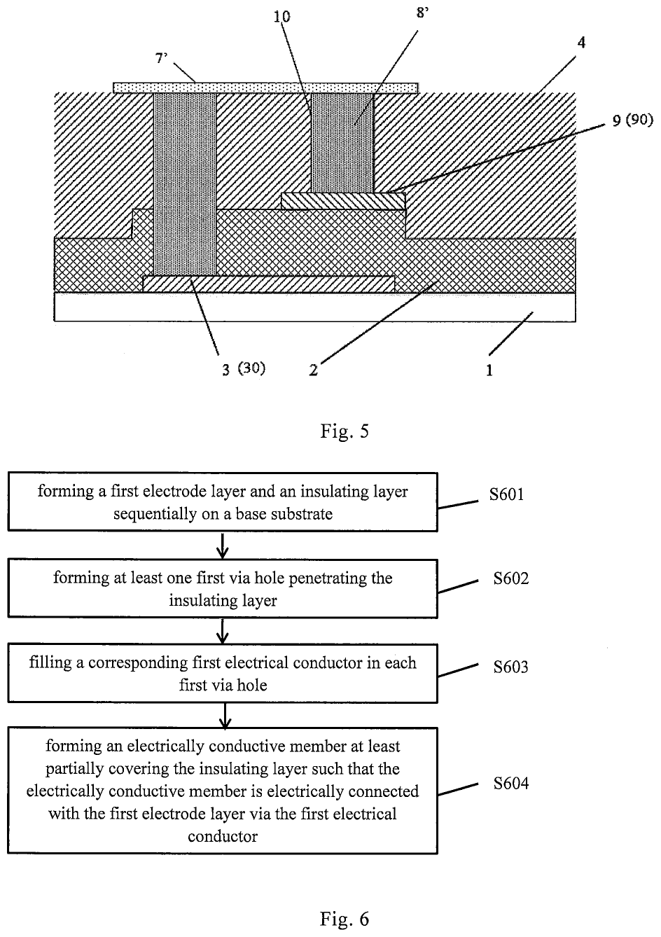

As shown in FIG. 5, according to an embodiment of this disclosure, the array substrate further includes a second electrode layer 9 insulated from the first electrode layer 3. Specifically, the second electrode layer 9 may be located between the first insulating layer 2 and the second insulating layer 4, and likewise, it may also include a plurality of second electrodes 90 arranged in an array for example. Similar to the first via hole 5′ in the embodiments described with reference to FIG. 3 and FIG. 4, in FIG. 5, the array substrate may further include at least one second via hole 10 passing through only the second insulating layer 4, so as to expose at least part of the second electrode layer 9 or the second electrodes 90 located below the second insulating layer 4, and a corresponding second electrical conductor 8′ is filled in each second via hole 10. In this way, the electrical connection between the transparent conductive layer 6 and the second electrode layer 9 can be achieved by means of the second electrical conductor 8′.

Optionally, in an embodiment of this disclosure, the first electrode layer 3 may be a gate layer, and the second electrode layer 9 may be a source/drain layer. In other words, in an embodiment of this disclosure, the first electrode layer 30 may include gates, and the second electrode layer 90 may include sources/drains.

Specifically, as shown in FIG. 5, in the display region of the liquid crystal display (also called Active Area; AA region) and/or the gate driver on array region (GOA region) of the array substrate, due to limited interior space, signals on the signal lines often need to be transmitted from the source/drain layer to the gate layer. Therefore, the transparent conductive layer 6 needs to be in electrical connection with both the gate layer and the source/drain layer at the same time. That is, in FIG. 5, the transparent conductive layer 6 is electrically connected with both the first electrode layer 3 and the second electrode layer 9 at the same time, thereby transmitting the signals on the signal line from the second electrode layer 9 to the first electrode layer 3. However, it is obvious that the transparent conductive layer 6 may also be electrically connected to only the first electrode layer 3, as shown in FIG. 4.

As compared with the array substrate according to the related art in FIG. 1, in the array substrate provided in the embodiments of this disclosure, the first electrical conductor 8 and the second electrical conductor 8′ are relatively independent from the first via hole 5′ and the second via hole 10, so abnormal ITO connection due to manufacturing process problems of the first via hole 5′ and the second via hole 10 will not be easily caused, which greatly enhances the entire performance of the liquid crystal display panel and improves the user experience.

In another aspect of this disclosure, a display panel is further provided in the embodiments, including the array substrate described in any of the above embodiments. Since the first electrical conductor 8 and/or the second electrical conductor 8′ in the array substrate will not be displaced or peeled off by the lateral extension of the corresponding insulating layer, the adverse effects on the display performance of the liquid crystal display panel are greatly reduced. According to yet another aspect of this disclosure, a display device is further provided in the embodiments, including the display panel described in any of the above embodiments.

According to still another aspect of this disclosure, a manufacturing method for an array substrate is further provided in the embodiments. As shown in FIG. 6, the manufacturing method may include steps as follows.

S601: forming a first electrode layer and an insulating layer sequentially on a base substrate.

S602: forming at least one first via hole passing through the insulating layer.

S603: filling a corresponding first electrical conductor in each first via hole.

S604: forming an electrically conductive member at least partially covering the insulating layer such that the electrically conductive member is electrically connected with the first electrode layer via the first electrical conductor.

Optionally, the material of the first electrical conductor includes a negative photoresist doped with electrically conductive particles. Furthermore, the step of filling a corresponding first electrical conductor in each first via hole includes: applying a negative photoresist doped with electrically conductive particles on the insulating layer on which the first via holes have been formed, and exposing and developing the negative photoresist by using a mask to form at least one first electrical conductor filled in a corresponding first via hole respectively. By doing this, both the production time and the production costs can be saved.

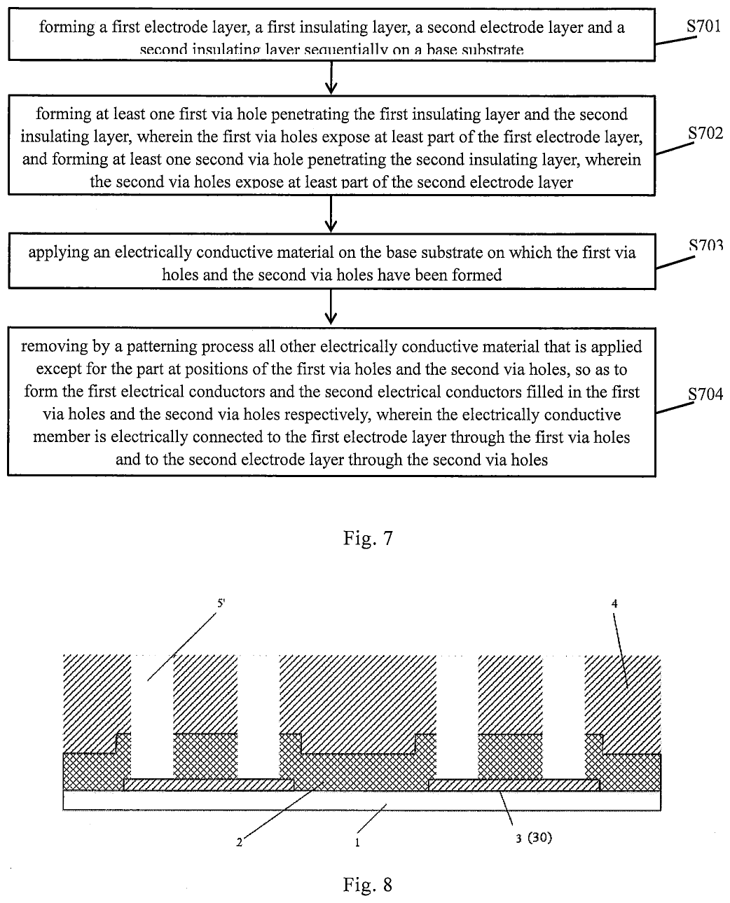

Specifically, in a specific embodiment of this disclosure, the insulating layer includes a first insulating layer and a second insulating layer, wherein the first insulating layer is close to the first electrode layer and the second insulating layer is located on the first insulating layer. FIG. 7 is a flow chart of a manufacturing method for an array substrate according to another embodiment of this disclosure. The manufacturing method may include steps as follows.

S701: forming a first electrode layer, a first insulating layer, a second electrode layer and a second insulating layer sequentially on a base substrate.

S702: forming at least one first via hole passing through the first insulating layer and the second insulating layer, wherein the first via holes expose at least part of the first electrode layer, and forming at least one second via hole passing through the second insulating layer, wherein the second via holes expose at least part of the second electrode layer.

S703: applying an electrically conductive material on the base substrate on which the first via holes and the second via holes have been formed.

S704: removing by a patterning process all other electrically conductive material that is applied except for the part at positions of the first via holes and the second via holes, to form the first electrical conductors and the second electrical conductors filled in the first via holes and the second via holes respectively, wherein the electrically conductive member is electrically connected to the first electrode layer through the first via holes and to the second electrode layer through the second via holes.

Specifically, in an embodiment of this disclosure, the via holes can be fabricated in the insulating layer by using the same mask for forming the insulating layer. However, it is obvious for those skilled in the art that the via holes may also be fabricated in the insulating layer by using other processes.

Optionally, in an embodiment of this disclosure, the photoresist for forming the first via holes and the second via holes in the insulating layer is a positive photoresist, so when the materials of the first electrical conductor and the second electrical conductor include a negative photoresist doped with electrically conductive particles, after the application of the negative photoresist doped with electrically conductive particles, the same mask for patterning the insulating layer to form via holes can be used to perform another exposure. In this way, the negative photoresist at positions of the first via holes and the second via holes can be retained. In other words, no new mask is required for the exposure. As can be seen, in the manufacturing method for an array substrate according to the embodiments of this disclosure, the process steps are very simple and the production costs can be further reduced.

The manufacturing method for an array substrate according to an embodiment of this disclosure will be introduced in detail with reference to the drawings.

As shown in FIG. 8, a first electrode layer 3, a first insulating layer 2 and a second insulating layer 4 are fabricated on a base substrate 1 sequentially by a patterning process for example. After that, at least one first via hole 5′ passing through the first insulating layer 2 and the second insulating layer 4 is formed by using a mask for instance such that at least part of the first electrode layer 3 is exposed. It should be pointed out that FIG. 8 only shows the situation in which the number of the first via holes 5′ is 4. However, those skilled in the art should understand that the number of the first via holes 5′ may also be increased or decreased upon actual needs. Besides, according to the embodiments of this disclosure, the first electrode layer 3, the first insulating layer 2, the second insulating layer 4 and the first via hole 5′ can be fabricated by using any suitable manufacturing process existing in the prior art, which will not be detailed for simplicity.

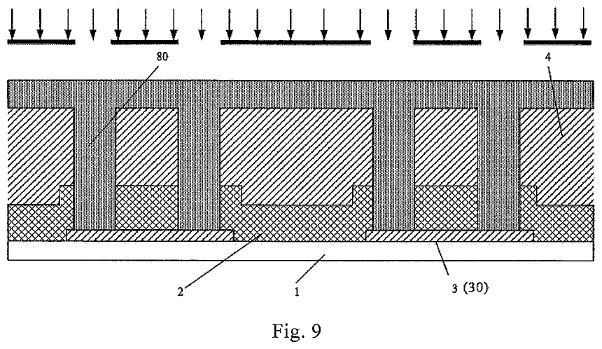

As shown in FIG. 9, after the initial structure of the array substrate as shown in FIG. 8 is obtained, an electrically conductive material 80 may be continuously applied onto the second insulating layer 4, wherein the electrically conductive material 80 can cover the top of the second insulating layer 4 and be filled in the first via holes 5′. Optionally, the material of the electrically conductive material 80 includes a negative photoresist doped with electrically conductive particles.

Next, as shown in FIG. 9, the mask for use in the second insulating layer 4 for example is used again to expose the electrically conductive material 80. In FIG. 9, the black horizontal line portion indicates the light shielding region of the mask, and the arrows indicate the direction of light during the exposure. After the exposure, a developing treatment is continued to remove the electrically conductive material 80 applied on the top of the second insulating layer 4, with only the electrically conductive material 80 filled in the first via holes 5′ retained. In this case, the electrically conductive material 80 filled in the first via holes 5′ constitute the first electrical conductors 8 according to an embodiment of this disclosure as shown in FIG. 3.

Further referring to FIG. 3, a flexible printed circuit 7 can be finally bound in a binding region such that the flexible printed circuit 7 can be electrically connected to the first electrode layer 3 via the first electrical conductor 8, thereby achieving transmission of the signals therebetween. According to an embodiment of this disclosure, in the manufacturing method for an array substrate, even if the first insulating layer 2 and/or the second insulating layer 4 are/is displaced or peeled off, due to its adhesiveness, the first electrical conductor 8 filled in the first via hole 5′ will not be displaced or peeled off by the lateral extension of the insulating layer, which greatly reduces the adverse effects on the display performance of the liquid crystal display panel. Besides, according to an embodiment of this disclosure, when the patterning process is applied on the second insulating layer 4 and the electrically conductive material 80, the exposure can be conducted by using only one mask, which considerably decreases the difficulty of process for manufacturing the array substrate and reduces the related manufacturing costs.

To sum up, according to an embodiment of this disclosure, in the array substrate, the first electrode layer (e.g., the gate layer) can be electrically connected with the electrically conductive member by means of the first electrical conductor filled in the first via hole. In this case, when the electrically conductor member includes a flexible printed circuit bound in the binding region of the array substrate, the flexible printed circuit bound in the binding region will be electrically connected to the first electrode layer by means of the first electrical conductor. Therefore, even if the insulating layer is displaced or peeled off, the first electrical conductor filled in the first via hole will not be displaced or peeled off by the lateral extension of the insulating layer. In this case, the flexible printed circuit still can be in electrical connection with the first electrode layer, thereby greatly reducing the adverse effects on the display performance of the liquid crystal display panel.

Besides, in the embodiments of this disclosure, the first electrical conductor and the second electrical conductor are relatively independent from the first via hole and the second via hole, so abnormal ITO connection due to manufacturing process problems of the first via hole and the second via hole will not be caused, which greatly enhances the entire performance of the liquid crystal display panel and improves the user experience.

What is mentioned above is only part of the embodiments of this disclosure. It should be pointed out that, for one having ordinary skills in the art, several improvements and modifications can also be made without departing from the principles of this disclosure, and such improvements and modifications should also be deemed as falling within the protection scope of this disclosure.

1. An array substrate, comprising:
a base substrate;
a first electrode layer, an insulating layer and an electrically conductive member on the base substrate stacked sequentially;
at least one first via hole through the insulating layer; and
at least one first electrical conductor,
wherein each first electrical conductor is in a corresponding first via hole to electrically connect the first electrode layer and the electrically conductive member.

2. The array substrate according to claim 1, wherein the electrically conductive member comprises a transparent conductive layer or a flexible printed circuit.

3. The array substrate according to claim 2, wherein the first electrical conductor comprises a negative photoresist doped with electrically conductive particles.

4. The array substrate according to claim 2,
wherein the first electrode layer comprises a plurality of first electrodes in an array, and
wherein each first electrode is electrically connected with the electrically conductive member via the at least one first electrical conductor.

5. The array substrate according to claim 2, wherein the insulating layer comprises a first insulating layer facing the first electrode layer and a second insulating layer on the first insulating layer.

6. The array substrate according to claim 5, further comprising:
a second electrode layer between the first insulating layer and the second insulating layer;
at least one second via hole through the second insulating layer; and
at least one second electrical conductor,
wherein each of the at least one second electrical conductor is in a corresponding second via hole to electrically connect the second electrode layer and the electrically conductive member.

7. The array substrate according to claim 6,
wherein the second electrode layer comprises a plurality of second electrodes in an array, and
wherein each second electrode is electrically connected with the electrically conductive member via the at least one second electrical conductor.

8. The array substrate according to claim 1,
wherein the first electrical conductor has a thickness greater than that of the insulating layer.

9. A display panel, comprising the array substrate according to claim 1.

10. A display device, comprising the display panel according to claim 9.

11. A manufacturing method for an array substrate, comprising:
forming a first electrode layer and an insulating layer sequentially on a base substrate;
forming at least one first via hole through the insulating layer;
filling a corresponding first electrical conductor in each first via hole; and
forming an electrically conductive member at least partially covering the insulating layer such that the electrically conductive member is electrically connected with the first electrode layer via the corresponding first electrical conductor.

12. The manufacturing method according to claim 11, wherein the of filling the corresponding first electrical conductor in each first via hole comprises:
applying a negative photoresist doped with electrically conductive particles on the insulating layer on which the first via holes have been formed, and
exposing and developing the negative photoresist by using a mask to form at least one first electrical conductor filled in a corresponding first via hole respectively.

13. The manufacturing method according to claim 11, wherein the insulating layer comprises a first insulating layer facing the first electrode layer and a second insulating layer on the first insulating layer, wherein the forming at least one first via hole through the insulating layer comprises forming at least one first via hole through the first insulating layer and the second insulating layer, and wherein the manufacturing method further comprises:
forming a second electrically conductive layer between the first insulating layer and the second insulating layer; and
forming at least one second via hole passing through the second insulating layer; and
filling a corresponding second electrical conductor in each second via hole to electrically connect the electrically conductive member and a second electrode layer.

14. The manufacturing method according to claim 13, wherein the filling the corresponding first electrical conductor in each first via hole and the filling a corresponding second electrical conductor in each second via hole are executed at a same time by performing operations comprising:
applying an electrically conductive material on the insulating layer on which the first via holes and the second via holes have been formed; and
removing by a patterning process other electrically conductive material that is applied except at positions of the first via holes and the second via holes, to form the at least one first electrical conductor and the corresponding second electrical conductor in the first via holes and the second via holes respectively.
